(19) United States
(12) Patent Application Publication
(10) Pub. No.: US 2011/0114938 A1
(43) Pub. Date: May 19, 2011

(54) ZnO SEMICONDUCTOR ELEMENT

(75) Inventors: Ken Nakahara, Kyoto (JP); Kentaro Tamura, Kyoto (JP); Hiroyuki Yuji, Kyoto (JP); Shunsuke Akasaka, Kyoto (JP); Masashi Kawasaki, Miyagi (JP); Akira Ohtomo, Miyagi (JP); Atsushi Tsukazaki, Miyagi (JP)

(73) Assignee: Rohm Co., Ltd., Kyoto (JP)

(21) Appl. No.: 12/735,798

(22) PCT Filed: Feb. 20, 2009
(86) PCT No.: PCT/JP2009/053074

§ 371 Date: Nov. 24, 2010

(30) Foreign Application Priority Data
Feb. 21, 2008 (JP) 2008-040118
Feb. 29, 2008 (JP) 2008-050906

(51) Int. Cl. H01L 29/12

(52) U.S. Cl. 257/43; 257/E29.068

(57) ABSTRACT

Provided is a ZnO-based semiconductor device in which, in the case of forming a laminate including an acceptor-doped layer made of a ZnO-based semiconductor, the properties of a film can be stabilized by preventing deterioration of the flatness of the acceptor-doped layer or a layer after the acceptor-doped layer and an increase of crystal defect in the layer, without lowering the concentration of an acceptor element.

### TECHNICAL FIELD

The present invention relates to a ZnO-based semiconductor device including, in a laminate structure, an acceptor-doped layer composed of ZnO or MgZnO.

### BACKGROUND ART

A ZnO-based semiconductor is expected to be applied to an ultraviolet LED used as a light source for illumination, backlight, or the like, a high-speed electronic device, a surface acoustic wave device, and so forth. Such ZnO-based semiconductor has drawn attention to its versatility, large light emission potential and the like. However, no significant development has been made on the ZnO-based semiconductor as a semiconductor device material. The largest obstacle is that p-type ZnO cannot be obtained because of difficulty in acceptor doping.

Nevertheless, as demonstrated by Non-patent Document 1 and Non-patent Document 2, technological progress of recent years has made it possible to produce p-type ZnO, and has proven that light is emitted from the p-type ZnO. For example, a proposal has been made on use of nitrogen as an acceptor for obtaining p-type ZnO. As disclosed in Non-patent Document 4, when ZnO is doped with nitrogen as an acceptor, the temperature of the substrate needs to be lowered because the efficiency of nitrogen doping heavily depends. on “a growth temperature. However, the lowering of the substrate temperature degrades crystallinity and forms a carrier compensation center that compensates, the acceptor, and thus nitrogen is not activated (self-compensation effect). This makes the formation of a p-type ZnO layer, itself, extremely difficult.

With this taken into consideration, Non-patent Document 2 has disclosed a method of forming a p-type ZnO-based layer with a high carrier density by using a −C plane as a principal surface for growth and also using repeated temperature modulation (RTM) in which a growth temperature is alternately changed between 400° C. and 1000° C., the method thereby taking advantage of the temperature dependency of the efficiency of nitrogen doping.

However, this method involves the following problems. The continuous process of heating and cooling results in the alternate repetition of thermal expansion and contraction of the manufacturing machine. This imposes heavy burden on the manufacturing machine. For this reason, the manufacturing machine requires an extensive configuration, and periodic maintenance service at shorter intervals. Furthermore, the method requires the temperature to be accurately controlled because the doping amount is determined by a part of the process at the lower temperature. However, it is difficult to control the temperature so that the temperature will reach 400° C. and 1000° C. accurately in a short time period, and the reproducibility and stability of the doping thus become inadequate. Further, since the method uses a laser as a heating source, the method is not suitable for heating a large area. In addition, it is difficult to grow multiple semiconductor films, although the growth of multiple semiconductor films is needed to reduce device manufacturing costs. The RTM is necessary because, when a −C plane of a ZnO substrate is used for crystal growth, nitrogen cannot be doped unless the temperature is lowered. This is peculiar to the growth on the −C plane.

On the other hand, as described in Non-patent Document 3, for example, it has been known that use of a +C plane of a ZnO substrate for a substrate for growth makes the doping of nitrogen easier. In this respect, the inventors carried out research in which a ZnO-based thin film was formed on a +C plane of a ZnO substrate by +C growth. As a result, it was discovered that conversion of a MgZnO thin film into p-type is easier than that of a ZnO thin film, and that the conversion into p-type is possible even in the growth at a constant temperature without using the RTM. Such discoveries are described in detail in Japanese Patent Application No. 2007-251482 and the like which have been filed.
Non-patent Document 1: A. Tsukazaki et al., JJAP 44 (2005) L643
Non-patent Document 2: A. Tsukazaki et al., Nature Material 4 (2005) 42
Non-patent Document 3: M. Sumiya et al., Applied Surface Science 223 (2004) p. 206
Non-patent Document 4: K. Nakahara et al., Journal of Crystal Growth 237-239 (2002) p. 503

### DISCLOSURE OF THE INVENTION

### Problems to be Solved by the Invention

However, even in the case where such a technique as described above is adopted, there still remains a problem. It occurs when a laminate structure of a semiconductor device is fabricated. When a ZnO-based thin film is laminated, the flatness of the thin film is important. A poor flatness of the thin film causes resistance to the migration of the carriers in the thin film. Further, as having larger surface roughness, a layer located more upward in the laminate structure is more likely to have such problems that uniformity in the depth of etching cannot be achieved due to the surface roughness, and growth of an anisotropic crystal surface occurs due to the surface roughness. Because of these reasons described above, it is likely to be difficult to allow a desired function as a semiconductor device to be exerted. Therefore, in general, it is desired that the surface of the thin film be as flat as possible.

In order to laminate a flat ZnO-based thin film, a growth temperature of 750° C. or above is required as indicated in Japanese Patent Application No. 2008-5987 and Japanese Patent Application No. 2007-27182, which have been filed. In the case of MgZnO, a further higher temperature is required in order to form a flat film. In the meantime, when a ZnO-based thin film is grown on a +C plane, nitrogen can be easily doped. However, the growth temperature dependency still exists, and therefore it becomes more difficult for nitrogen to be doped as a temperature becomes higher.

In the case of an n-type layer of a ZnO-based thin film, even if it is formed by crystal growth at a high temperature, there would arise no problem in doping of n-type impurities or in the flatness of the film. Meanwhile, in fabrication of an acceptor-doped layer, it is necessary to lower the growth temperature as described above in order to increase the concentration of a doped acceptor element. However, when the growth temperature is lowered, roughness occurs on the surface of the film. For this reason, in the case of laminating a ZnO-based thin film, if an acceptor-doped layer is laminated after an n-type layer is fabricated, roughness occurs on the surface of the acceptor-doped layer. On the other hand, if an n-type layer is laminated after an acceptor-doped layer is fabricated, roughness on the acceptor-doped layer propagates, resulting in poor surface flatness. Therefore, there arises a problem that a desired function as a semiconductor device cannot be exerted.

On the other hand, in the case of using ZnO for an acceptor-doped layer or the like, there are some difficult problems involved in the ZnO in terms of its properties. One generally well known is change in the electric properties caused by annealing. In a state of low oxygen, the concentration of electrons increases, and thereby the resistance is lowered. In a state where oxygen is available, both the concentration and the mobility of electrons decrease, and thereby the resistance is increased. This means that, during the process from the time ZnO is grown to the completion of the device, or during the operation, the properties of the film of ZnO could change and the properties of the film are likely to change depending on the growth temperature of the film. These are the characteristics that are problematic especially in electronic devices.

This indicates that ZnO is likely to have composition deviation. As many oxides do, ZnO has a nature of shifting to Zn-rich side as Zn_{1+δ}O_{1-δ}. For this reason, the degree of the Zn rich increases due to annealing in a low-oxygen state, while the degree of the Zn rich decreases due to annealing in a high-oxygen state. In semiconductor devices, it is necessary to stabilize an undoped state in order to achieve an intended conductivity control; however, undoped ZnO slightly lacks stability. For this reason, in the case particularly of doping with an acceptor, such as nitrogen, it is likely that a compensation level is automatically formed (self-compensation effect), and roughness of the film surface or the like is caused by inhibition of migration of surface atoms due to point defect growth.

Further, ZnO is highly c-axis oriented, and frequently forms a film like a gathering of hexagonal columns. In this event, there is a region called a grain boundary among the hexagonal columns, and a potential barrier is formed in this region. This nature is used successfully in a ZnO varistor. However, since a crystal defect is generated, such a crystal defect causes an increase in the operating voltage, and a leak current. There occurs a phenomenon in which the degree of such an increase varies among fabricated films, and this becomes problematic as well especially in electronic devices.

In addition to these, as described in detail in Japanese Patent Application No. 2007-221198 which has been filed by the inventors, since the surface of a ZnO film is likely to become rough due to doping of nitrogen required for conversion into p-type, there arises a problem, especially in the case of MBE growth, that the roughness of the film surface induces contamination of unintended impurities, such as Si. Although the grounds are not obvious, it is inferred that this is highly possibly associated with the fact that defect is liable to occur in ZnO.

The present invention has been made to solve the above-described problems, and an object thereof is to provide a ZnO-based semiconductor device in which, in the case of forming a laminate including an acceptor-doped layer made of a ZnO-based semiconductor, the properties of a film can be stabilized by preventing deterioration of the flatness of the acceptor-doped layer or a layer after the acceptor-doped layer and an increase of crystal defect in the layer, without lowering the concentration of an acceptor element.

### Means for Solving the Problems

To achieve the above object, the ZnO-based semiconductor device of the present invention is summarized as a ZnO-based semiconductor device formed by laminating a ZnO-based semiconductor on a substrate by crystal growth, the ZnO-based semiconductor device comprising an acceptor-doped layer which is composed of Mg_{Y}Zn_{1-Y}O (0<Y<1) and contains at least one kind of an acceptor element, wherein an undoped or donor-doped Mg_{X}Zn_{1-X}O (0<X<1) layer is formed in contact with the acceptor-doped layer.

The ZnO-based semiconductor device of the present invention is also summarized as a ZnO-based semiconductor device formed by laminating a ZnO-based semiconductor on a substrate by crystal growth, the ZnO-based semiconductor device comprising: an acceptor-doped layer which is composed of Mg_{Y}Zn_{1-Y}O (0<Y<1) and contains at least one kind of an acceptor element; and an n-type Mg_{Z}Zn_{1-Z}O (0<Z<1) layer which contains at least one kind of a donor element, wherein an undoped or donor-doped Mg_{X}Zn_{1-X}O layer is formed to be located between the acceptor-doped layer and the n-type Mg_{Z}Zn_{1-Z}O layer and be in contact with any one of these two layers.

### Effects of the Invention

According to the present invention, when a laminate including an acceptor-doped layer made of a ZnO-based semiconductor is formed, an undoped or donor-doped MgZnO layer is formed in contact with the acceptor-doped layer. Further, in the case where the laminate includes the acceptor-doped layer and an n-type Mg_{Z}Zn_{1-Z}O layer, the undoped or donor-doped MgZnO layer is formed to be located between the acceptor-doped layer and the n-type Mg_{Z}Zn_{1-Z}O layer and be in contact with any one of these two layers. Further, in both cases above, the acceptor-doped layer is composed of MgZnO containing Mg.

Accordingly, due to the base effect of the MgZnO layer and the properties of MgZnO itself, deterioration of the flatness of the acceptor-doped layer or the layer after the acceptor-doped layer and an increase of crystal defect in the layer can be prevented without lowering the concentration of the acceptor element of the acceptor-doped layer. Further, the properties and nature of the acceptor-doped layer can be stabilized.

### BRIEF DESCRIPTION OF THE DRAWINGS

FIG. 1 is a diagram showing an example of a laminate structure of a ZnO-based semiconductor device of the present invention.

FIG. 2 is a diagram showing a difference in the laminate structure between the cases of using MgZnO and ZnO, respectively, as a base of an acceptor-doped layer.

FIG. 3 is a diagram showing states of the surfaces of acceptor-doped layers corresponding to the respective laminate structures in FIG. 2.

FIG. 4 is a diagram showing the surface state and a PL luminescence spectrum, in the case of laminating layers in the sequence of ZnO substrate/ZnO.

FIG. 5 is a diagram showing the surface state and a PL luminescence spectrum, in the case of laminating layers in the sequence of ZnO substrate/MgZnO/ZnO.

FIG. 6 is a diagram showing the surface state and a PL luminescence spectrum, in the case of laminating layers in the sequence of ZnO substrate/MgZnO/MQW.

FIG. 7 is a diagram showing the surface state in the case of laminating layers in the sequence of ZnO substrate/MgZnO.

FIG. 8 is a diagram showing the surface state in the case of laminating layers in the sequence of ZnO substrate/MgZnO/ZnO.

FIG. 9 is a diagram showing the surface state in the case of laminating layers in the sequence of ZnO substrate/ZnO.

FIG. 10 is a diagram showing the surface states of a MgZnO monolayer and a ZnO/MgZnO multilayer film, respectively.

FIG. 11 is a diagram showing a different example of a laminate structure of the ZnO-based semiconductor device of the present invention.

FIG. 12 is a diagram showing the growth temperature dependency of nitrogen concentration.

FIG. 13 is a diagram showing a difference in the growth temperature between the cases of fabricating flat MgZnO and ZnO, respectively.

FIG. 14 is a diagram showing the relationship between the arithmetic mean roughness of the surface of a ZnO-based thin film and the temperature of a substrate.

FIG. 15 is a diagram showing the relationship between the root mean square roughness of the surface of a ZnO-based thin film and the temperature of a substrate.

FIG. 16 is a diagram showing the surface shapes of MgZnO and ZnO, respectively, when nitrogen is added.

FIG. 17 is a diagram showing the relationship between the surface flatness shown in FIG. 16 and the concentration of Si contamination.

FIG. 18 is a diagram showing chronological changes in the PL luminescence intensities of MgZnO and ZnO, respectively.

FIG. 19 is a diagram for comparison in IV characteristics between MgZnO and ZnO.

FIG. 20 is a diagram showing an example of an LED structure using an MgZnO layer.

FIG. 21 is a diagram showing an example of a PD structure using an MgZnO layer.

FIG. 22 is a diagram illustrating the PL luminescence spectra of MgZnO and ZnO to both of which nitrogen is added.

FIG. 23 is a diagram illustrating the PL luminescence spectra of MgZnO and ZnO to both of which nitrogen is added.

FIG. 24 is a diagram illustrating the PL luminescence spectra of MgZnO and ZnO to both of which nitrogen is added.

### DESCRIPTION OF SYMBOLS

1 ZnO substrate
2 n-type Mg_{Z}ZnO layer
3 undoped MgZnO layer
4 MQW active layer
5 undoped Mg_{X}ZnO layer
6 acceptor doped Mg_{Y}ZnO layer

### BEST MODES FOR CARRYING OUT THE INVENTION

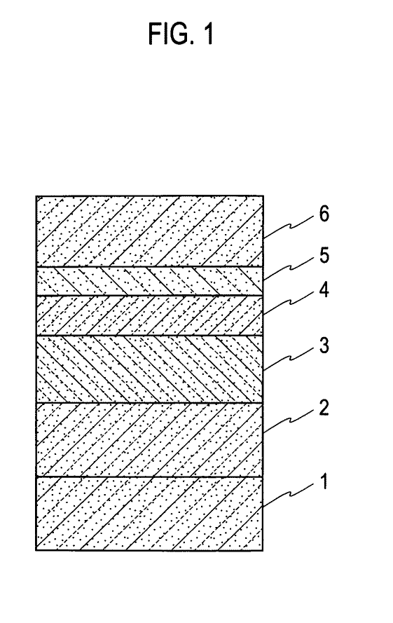

Hereinafter, an embodiment of the present invention will be described by referring to the drawings. The drawings are schematic, and thus differ from the actual. Additionally, some components may differ in dimensional relation and ratio in one drawing from the others. FIG. 1 shows an example of a laminate structure of a ZnO-based semiconductor device of the present invention.

On a ZnO substrate 1 serving as a substrate for growth, an n-type Mg_{Z}Zn_{1-Z}O (0≦Z<1) layer 2, an undoped MgZnO layer 3, an MQW active layer 4, an undoped Mg_{X}Zn_{1-X}O (0<X<1) layer 5, and an acceptor doped Mg_{Y}Zn_{1-Y}O (0<Y<1) layer 6 are sequentially laminated. Herein, in order to simplify the notations of the n-type Mg_{Z}Zn_{1-Z}O layer 2, the undoped Mg_{X}Zn_{1-X}O layer 5, the acceptor-doped Mg_{Y}Zn_{1-Y}O layer 6, and the like, they are described as the n-type Mg_{Z}ZnO layer 2, the undoped Mg_{X}ZnO layer 5, and the acceptor-doped Mg_{Y}ZnO layer 6, respectively. Hereinafter, the same applies to other notations.

Further, a ZnO-based semiconductor or a ZnO-based thin film is composed of ZnO or a compound containing ZnO, and specific examples of which include, in addition to ZnO, respective oxides of a IIA group element with Zn, a IIB group element with Zn, and a IIA group element and a IIB group element with Zn.

The MQW active layer 4 is, for example, formed to be a multi-quantum well structure having a barrier layer Mg_{0.15}ZnO and a well layer ZnO which are alternately laminated to each other. The acceptor doped Mg_{Y}ZnO layer 6 is doped with at least one kind of acceptor element. As the acceptor element, nitrogen, phosphorus, arsenic, lithium, copper, or the like is used. As a donor element added to the n-type Mg_{Z}ZnO layer 2, at least one kind is selected from the III group elements. Accordingly, two kinds or more may be doped, and B (borate), Al (aluminum), Ga (gallium), and the like are available as the donor element.

Further, the undoped Mg_{X}ZnO layer 5 corresponds to an undoped or donor-doped Mg_{X}Zn_{1-X}O (0<X<1) layer, and may be a donor-doped Mg_{X}ZnO layer. The donor element of this case may be selected similarly to the case of the n-type Mg_{Z}ZnO layer 2. Further, the undoped Mg_{X}ZnO layer 5 and the acceptor-doped Mg_{Y}ZnO layer 6 have Mg compositions in the ranges 0<X and 0<Y, respectively, and are composed of MgZnO certainly containing Mg. In the meantime, it is desirable to set the upper limit of the Mg compositions to be 0<X≦0.5 and 0<Y≦0.5, respectively. This is because at present, the Mg composition ratio at which a uniform MgZnO mixed crystal can be fabricated is 50% or less. In order to fabricate a uniform MgZnO mixed crystal more reliably, it is more preferable to set the Mg composition ratio to be 30% or less.

Here, when ZnO (zinc oxide) or MgZnO (magnesium zinc oxide) is doped with a donor element, it becomes n-type in general. In the meantime, when it is doped with an acceptor element, although depending on the amount of the doping, it may not become a p-type semiconductor because the acceptor element is not necessarily activated due to the self compensation effect or the like. Accordingly, the acceptor-doped layer includes a p-type semiconductor and an i-type semiconductor (intrinsic semiconductor).

The characteristic points in the structure shown in FIG. 1 are, in fabrication of the acceptor-doped layer: using of an undoped MgZnO layer as a base; and forming of the acceptor-doped layer with MgZnO. Due to the insertion of an undoped MgZnO layer between the n-type layer and the acceptor-doped layer as well as the use of MgZnO also in the acceptor-doped layer in the lamination of a ZnO-based semiconductor, as described above, it is possible to incorporate a large amount of the acceptor element into the acceptor-doped layer and to prevent the roughness of the surface of the acceptor-doped layer.

Hereinafter, the operation and effect mentioned above will be described. First, as described in Background Art, when a ZnO-based thin film is grown on a +C plane with use of the +C plane of a ZnO substrate, an acceptor element can be easily doped. However, the growth temperature dependency still exists, and therefore it becomes more difficult for the acceptor element to be doped as a temperature becomes higher.

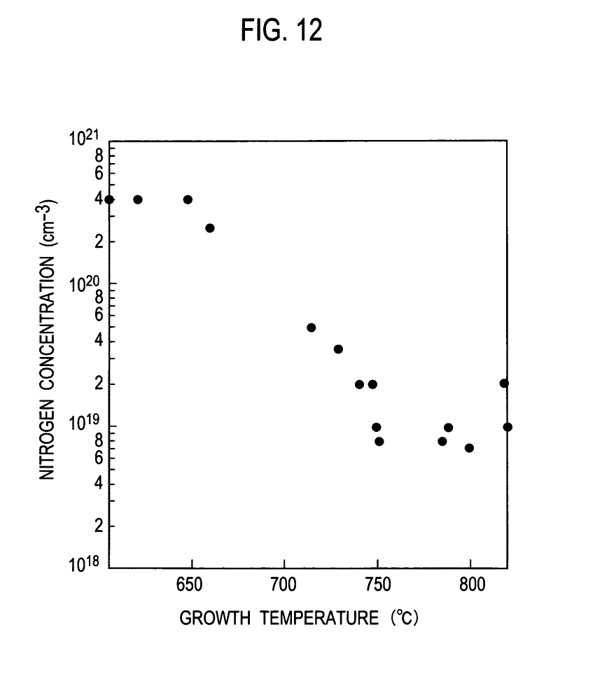

FIG. 12 shows the relationship between the crystal growth temperature (substrate temperature) and the concentration of nitrogen in a ZnO thin film. The characteristic in the range of growth temperature between approximately 600° C. and 850° C. is shown. This is a result of growth of a ZnO thin film with the doping of a +C plane of a ZnO substrate with nitrogen, which is a kind of acceptor element. The vertical axis represents the concentration of nitrogen (cm⁻³)incorporated into the ZnO thin film when nitrogen is doped whereas the horizontal axis represents the growth temperature (substrate temperature: unit ° C.). As shown in FIG. 12, with the ZnO-based thin film, the concentration of nitrogen, which is a kind of acceptor element, still has temperature dependency even with use of the +C plane, and the concentration of doped nitrogen increases as the temperature is lowered. Accordingly, in order to convert the ZnO-based thin film into p-type by incorporating a sufficient amount of nitrogen, the substrate temperature needs to be lowered. However, when the substrate temperature is lowered, a problem as described below regarding the surface flatness arises.

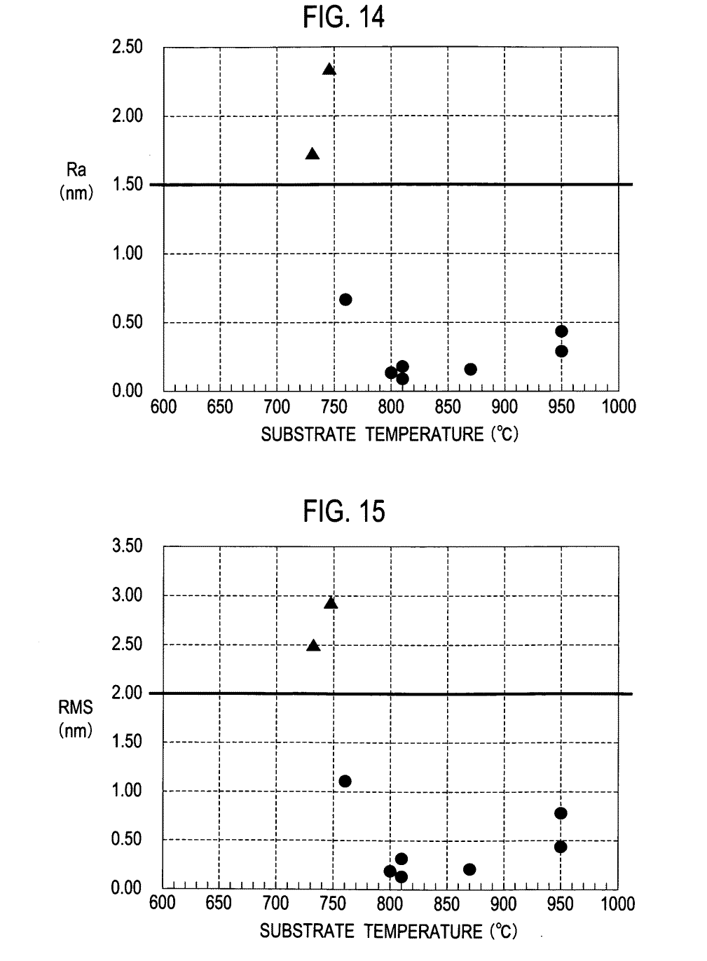

The relationship between the surface flatness and the growth temperature in the case of forming a ZnO thin film is described in detail in Japanese Patent Application No. 2008-5987 which has been filed, but the main points thereof will be described herein again. A ZnO thin film is formed on a MgZnO substrate by crystal growth at various substrate temperatures (growth temperatures), and the flatness of the surface of ZnO at each substrate temperature is expressed in number, and thus-obtained numbers are plotted in a graph to obtain FIG. 14. The vertical axis Ra (the unit is nm) of FIG. 14 represents the arithmetic mean roughness of the film surface. The arithmetic mean roughness Ra is calculated from a roughness curve.

To obtain the roughness curve, the irregularities on the film surface which are observed in AFM (atomic force microscope) measurement or the like are measured at predetermined sampling points. Then, the sizes of the irregularities are shown together with the average value of these irregularities. Thereafter, a reference length l is extracted from the roughness curve towards the average line. The absolute values of the deviations from the average line of the extracted portions to the measured curve are summed up and averaged out. The arithmetic mean roughness Ra is expressed as Ra=(1/l)×∫|f(x)|dx (integral interval is from 0 to 1). A stable result can be obtained in this way because the influence that a single flaw exerts on the measured value can be significantly reduced. Incidentally, the parameters of surface roughness such as the arithmetic mean roughness Ra and the like are defined by JIS standards. The inventors employ these parameters.

In FIG. 14, the vertical axis represents the arithmetic mean roughness Ra calculated in the above-described way whereas the horizontal axis represents the temperature of the substrate. The black triangles (▴) in FIG. 14 represent the data obtained at substrate temperatures under 750° C. whereas the black circles () represent the data obtained at substrate temperatures of 750° C. and higher. As can be seen from

FIG. 14, if the substrate temperature reaches 750° C. and rises even higher, the flatness of the surface improves drastically.

FIG. 15 shows root mean square roughness RMS of the film surface calculated from the same measured data as used in the case of FIG. 14. The root mean square roughness RMS is the square root of the average value for the sum of the squared deviations from the average line of the roughness curve to the measured curve. With the reference length l used in the calculation of the arithmetic mean roughness Ra, the root mean square roughness RMS is expressed as

RMS={(1/l)×∫(f(x))²dx}^{1/2} (integral interval is from 0 to 1)

In FIG. 15, the vertical axis represents the root mean square roughness RMS whereas the horizontal axis represents the temperature of the substrate. The black triangles (▴) represent the data obtained at substrate temperatures under 750° C. whereas the black circles () represent the data obtained at substrate temperatures of 750° C. and higher. In regard to the temperature of the substrate, similarly to FIG. 14, it can be seen that, if the substrate temperature reaches 750° C. and rises even higher, the flatness of the surface improves drastically.

Accordingly, when a ZnO-based thin film is grown on a ZnO-based material, a film having good flatness can be obtained by an epitaxial growth process performed with the substrate temperature kept at 750° C. or higher, and a flat film can be obtained as well at the uppermost layer in the laminate structure.

However, as shown in FIG. 12, even in the growth on a +C plane, the amount of nitrogen doping depends on the growth temperature; therefore, the growth temperature of a ZnO-based thin film has to be set to be under 750° C., if a sufficient amount of nitrogen doping should be acquired. According to FIGS. 14 and 15, however, the surface flatness is significantly deteriorated at a temperature under 750° C. In addition, the temperature for step-flow growth of MgZnO is higher than that of ZnO.

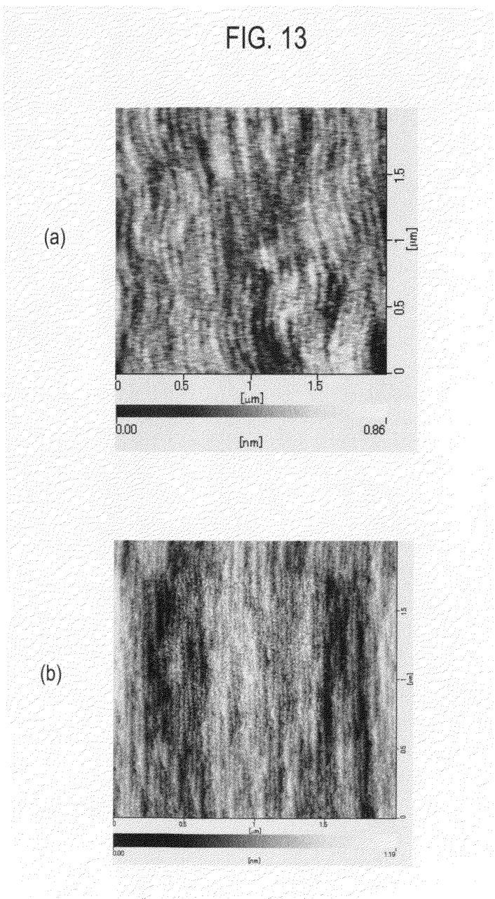

FIG. 13 shows that the temperature of step-flow growth of MgZnO increases. FIG. 13(a) is an image obtained by scanning a 2-μm square area of the surface of a ZnO thin film grown on a ZnO substrate by use of AFM whereas FIG. 13(b) is an image obtained by scanning a 2-μm square area of the surface of a MgZnO thin film grown on a ZnO substrate by use of AFM.

The ZnO thin film shown in FIG. 13(a) has a growth temperature of 790° C., whereas the MgZnO thin film shown in FIG. 13(b) has a growth temperature of 880° C. While the surface flatness of the MgZnO thin film is maintained at a growth temperature of approximately 880° C., the surface flatness of the ZnO thin film is maintained even at 790° C. As can be seen here, a MgZnO thin film requires a higher temperature for the growth than a ZnO thin film. Accordingly, it is assumed that, if the growth temperature is set to be low for the purpose of increasing the concentration of doped nitrogen, the surface flatness of a MgZnO thin film is more affected.

As described in Japanese Patent Application No. 2007-221198 which has been filed, surface roughness of a ZnO-based semiconductor causes doping with unintended impurities, and thereby interfering the conversion into p-type. In particular among such impurities, Si is one of the elements included in a discharge tube of a radical cell, in which active oxygen is produced by making O₂ plasma, and is the substance that is mixed in the most. When incorporated into the film, Si works as a donor. Accordingly, a higher concentration of Si contamination makes the conversion into p-type more difficult. Therefore, it is important to obtain a flat surface of the film.

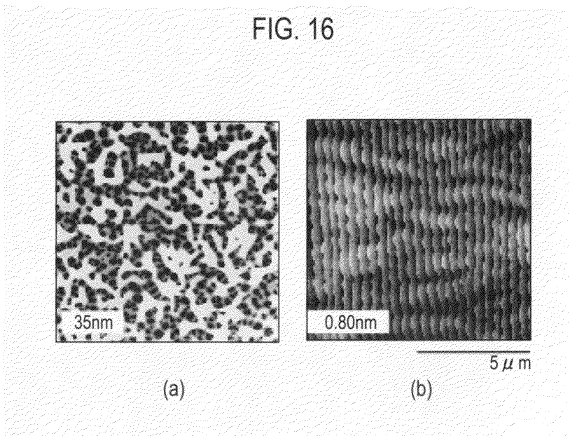

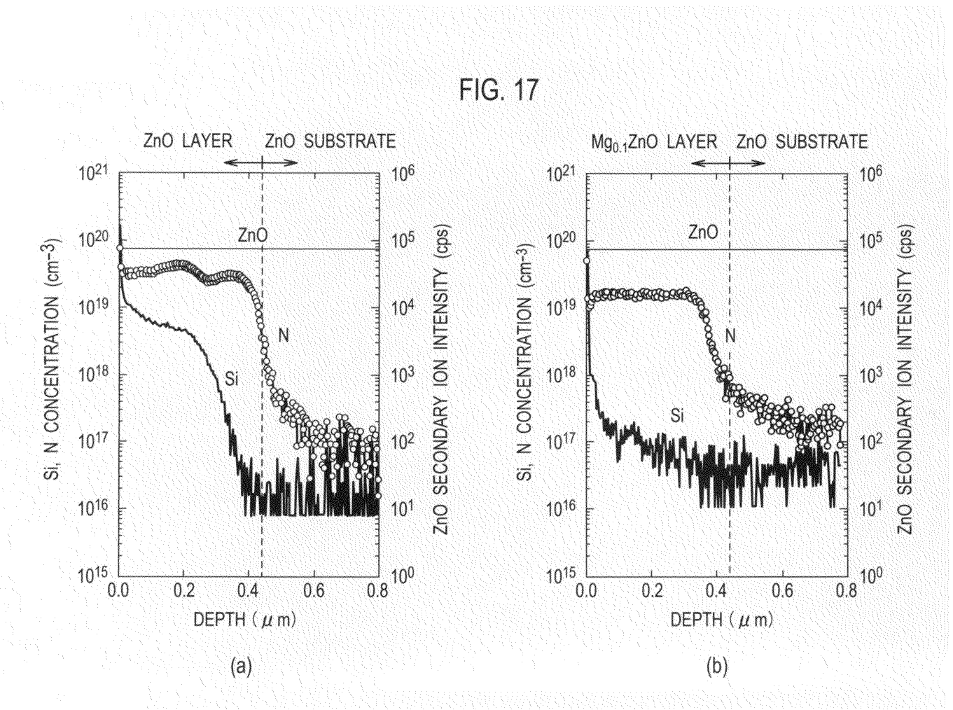

Data shown in FIGS. 16 and 17 were obtained from the investigation in which a nitrogen-doped Mg_{X}ZnO thin film was formed on a ZnO substrate by an epitaxial growth performed in an MBE (Molecular Beam Epitaxy) apparatus having a radical cell. In addition, the silicon concentration and the nitrogen concentration in the Mg_{X}ZnO thin film were measured by the secondary ion mass spectroscopy (SIMS).

FIG. 16(a) shows an image of a surface obtained by doping ZnO (X=0) with 3×10¹⁹ cm⁻³ of nitrogen at a substrate temperature of 750° C. in nitrogen doping by nitrogen monoxide (NO) plasma. In the meantime, FIG. 16(b) shows an image of a surface obtained by doping Mg_{0.1}ZnO with 1×10¹⁹ cm⁻³ of nitrogen at a substrate temperature of 750° C. in nitrogen doping by nitrogen monoxide (NO) plasma. These surface images are obtained by use of ARM (Atomic Force Microscope) in a scanning area of 10-μm square for both FIGS. 16(a) and (b), and the numerals in the diagrams are RMS (Root Mean Square) values.

As can be seen from the comparison between these images, the surface roughness occurs in the nitrogen-doped ZnO at a low temperature. However, even in nitrogen doping at the same low temperature, no surface roughness occurs with Mg_{0.1}ZnO. Accordingly, in the case of doping with an acceptor, MgZnO containing a component of Mg is more preferable as well for the purpose of fabricating a flat film.

FIG. 17 shows that, in a ZnO-based semiconductor, the surface roughness causes doping with unintended impurities, and interferes the conversion into p-type. In FIG. 17, Si is taken as an example of such unintended impurities. FIG. 17(a) shows the concentration of doped nitrogen and the concentration of Si contamination in the ZnO layer shown in FIG. 16(a). In the meantime, FIG. 17(b) shows the concentration of doped nitrogen and the concentration of Si contamination in the Mg_{0.1}ZnO layer shown in FIG. 16(b).

In both FIGS. 17(a) and (b), the vertical axis on the left-hand side represents either the Si concentration or the N concentration whereas the vertical axis on the right-hand side represents the secondary ion intensity of ZnO, and the horizontal axis represents the depth (μm). The vertical dotted line in the diagram indicates the boundary between the ZnO substrate and the Mg_{X}ZnO thin film, and the region where the nitrogen concentration and the silicon concentration are increasing corresponds to either the ZnO layer or the Mg_{0.1}ZnO layer, whereas the region where the nitrogen concentration and the silicon concentration are almost as low as zero corresponds to the ZnO substrate.

As can be understood from this diagram, the concentration of Si contamination in the thin film is higher in the ZnO layer having a poorer surface flatness (roughened surface) shown in FIG. 16(a). When incorporated into the film, Si works as a donor. Accordingly, a higher concentration of Si contamination makes the conversion into p-type more difficult. Therefore, from the viewpoint of flattening the film surface and preventing contamination of impurities, MgZnO containing a component of Mg is more preferable.

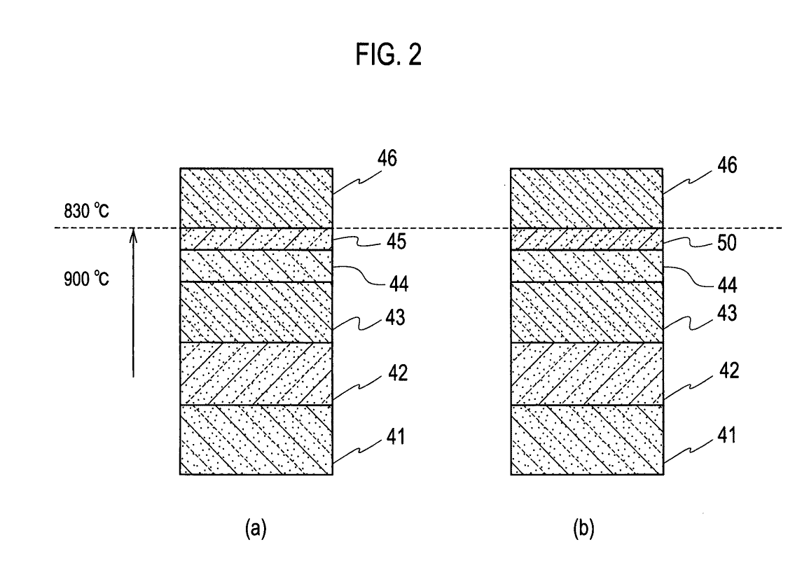

Then, as shown in FIG. 1, in fabrication of an acceptor-doped layer, the surface flatness of the acceptor-doped layer is improved by using an undoped or donor-doped MgZnO layer as a base and using MgZnO as well in the acceptor-doped layer. FIG. 2 shows the difference in the effects between the cases where a MgZnO layer is used as a base and not used, in fabrication of an acceptor-doped layer. In FIG. 2(a), a Ga-doped MgZnO layer 42, an undoped MgZnO layer 43, a laminate 44, an undoped ZnO layer 45, and a nitrogen-doped MgZnO layer 46 are sequentially formed on a ZnO substrate 41. The Ga-doped MgZnO layer 42 to the undoped ZnO layer 45 were grown at a growth temperature of 900° C., while the nitrogen-doped MgZnO layer 46 was grown at a low growth temperature of 830° C. in order to increase the concentration of nitrogen.

Meanwhile, in FIG. 2(b), a Ga-doped MgZnO layer 42, an undoped MgZnO layer 43, a laminate 44, an undoped MgZnO layer 50, and a nitrogen-doped MgZnO layer 46 are sequentially formed on a ZnO substrate 41. The Ga-doped MgZnO layer 42 to the undoped MgZnO layer 50 were grown at a growth temperature of 900° C., while the nitrogen-doped MgZnO layer 46 was grown at a low growth temperature of 830° C. in order to increase the concentration of nitrogen.

The laminate 44 is a super-lattice layer, and made with a laminate obtained by alternately laminating an undoped ZnO and an undoped MgZnO for 10 cycles. Further, the Ga-doped MgZnO layer 42, the nitrogen-doped MgZnO layer 46, and the undoped MgZnO layer 50 correspond to the n-type Mg_{Z}ZnO layer, the acceptor-doped layer (Mg_{Y}ZnO layer), and the undoped or donor-doped Mg_{X}ZnO layer, respectively.

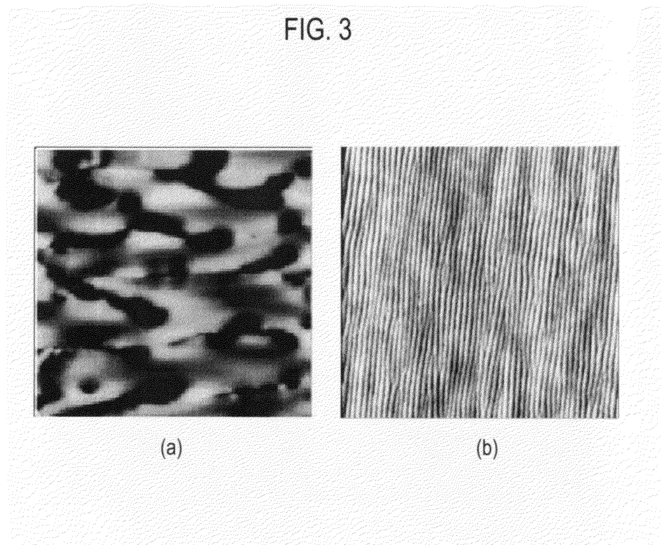

Between FIGS. 2(a) and (b), the only difference is whether the undoped ZnO layer 45 or the undoped MgZnO layer 50 is used as a base of the nitrogen-doped MgZnO layer 46, and other layer structures, growth temperatures, and the like are the same. The surface conditions of the uppermost layers of these laminate structures are compared in FIG. 3. FIG. 3(a) shows the surface of the nitrogen-doped MgZnO layer located in the uppermost layer of FIG. 2(a) whereas FIG. 3(b) shows the surface of the nitrogen-doped MgZnO layer 46 located in the uppermost layer of FIG. 2(b). These are images obtained by scanning in AFM measurement. FIG. 3(b) has a finer surface without roughness, and this is considered to be due to the effect of using the undoped MgZnO layer 50 as a base of the nitrogen-doped MgZnO layer 46 in FIG. 2(b).

Next, it will be described that the density of crystal defects is reduced by use of MgZnO. The density of crystal defects causes contamination of unintended impurities as well as in the problem regarding the surface flatness described above; therefore, it is desirably lowered as much as possible.

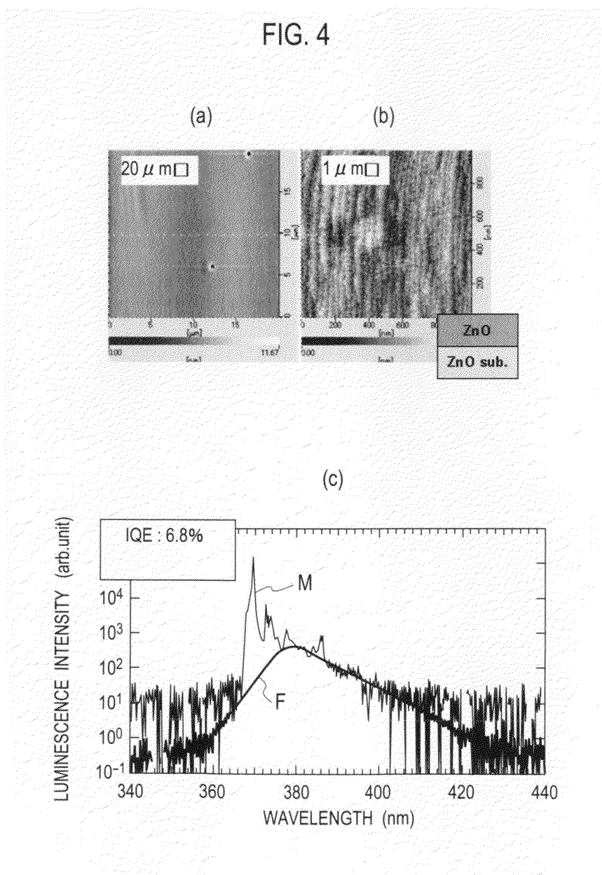

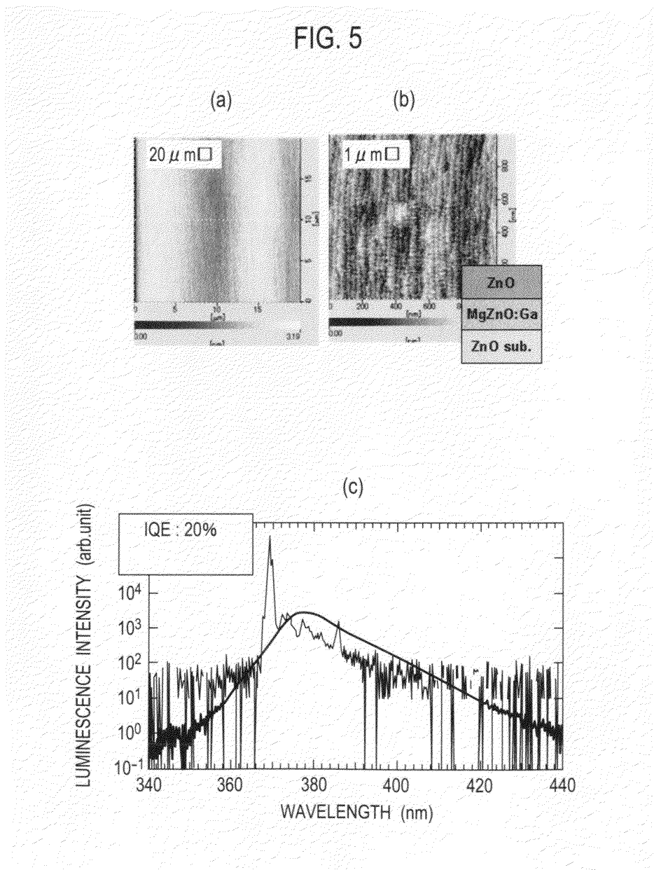

FIG. 4 is an observation by AFM of the surface of a ZnO thin film grown on a ZnO substrate as illustrated on the bottom right of FIG. 4(b). Meanwhile, FIG. 5 is an observation by AFM of the surface of a ZnO thin film of a laminate structure of ZnO substrate/Ga-doped MgZnO/ZnO obtained by growing a Ga (gallium)-doped MgZnO thin layer on a ZnO substrate and further forming a ZnO thin layer thereon, as illustrated on the bottom right of FIG. 5(b).

The numeral shown on the upper left of each image shows a range of the visual field of AFM, which is either 20 pm-square area or 1 pm-square area. In either case, the growth temperature was 800° C. Further, results of PL (photoluminescence) measurement performed on these configurations are shown in FIG. 4(c) and FIG. 5(c). The horizontal axis represents the wavelength (nm) whereas the vertical axis represents the luminescence intensity (arbitrary unit). Of the spectrum curves, a measured curve M is a result at an absolute temperature of 12 K whereas F is a result at room temperature. Further, IQE represents the internal quantum efficiency. In the diagram (a), black spots are observed. They are dislocation defects appearing on the surface. The results of the measurement revealed that the defect density for the case shown in FIG. 4 was 3.6×10⁵ cm⁻² whereas the defect density for the case shown in FIG. 5 was 6.1×10⁴ cm⁻². As can be understood from the comparison between FIG. 4 and FIG. 5, use of MgZnO as a base for the crystal growth of a ZnO thin film decreased the crystal defect density and largely increased the internal quantum efficiency from 6.8% to 20%.

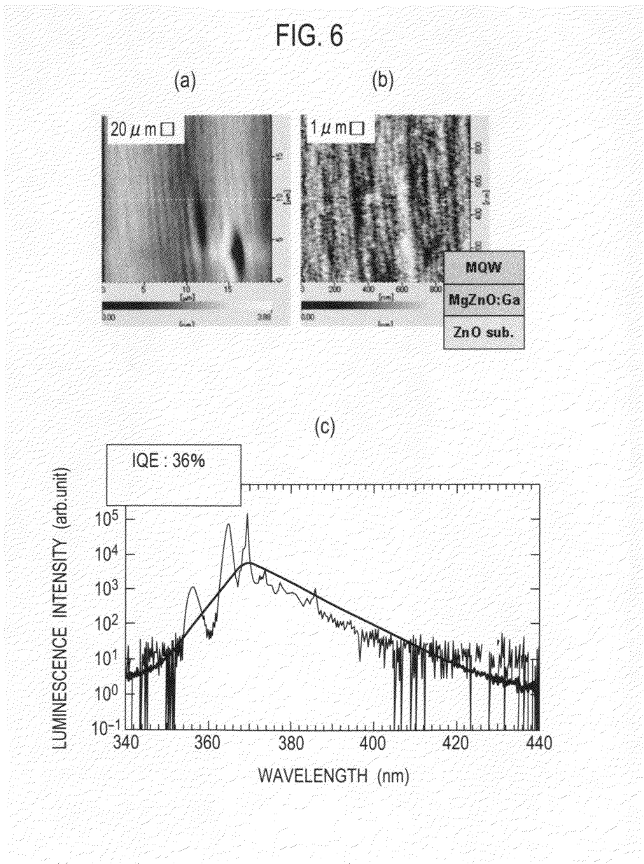

FIG. 6 shows the state of the surface of an MQW layer of a laminate structure of ZnO substrate/Ga-doped MgZnO/MQW layer, as shown in (b), formed at a growth temperature of 870° C. In this case, the MQW layer was made with a laminate obtained by alternately laminating an undoped ZnO film having a film thickness of 2 nm and an undoped MgZnO film having a film thickness of 2 nm for 10 cycles. As described above, the surface of the MQW layer was photographed in a 20-μm square visual field and a 1-μm square visual field by using AFM. The density of crystal defects was 7.2×10⁴ cm⁻². Further, the result of the PL measurement is shown in (c), and the internal quantum efficiency (IQE) was 36%. As revealed in the result of the PL measurement, the internal quantum efficiency was largely improved, compared to the case in FIG. 5, by use of the MQW (Multi Quantum Well structure).

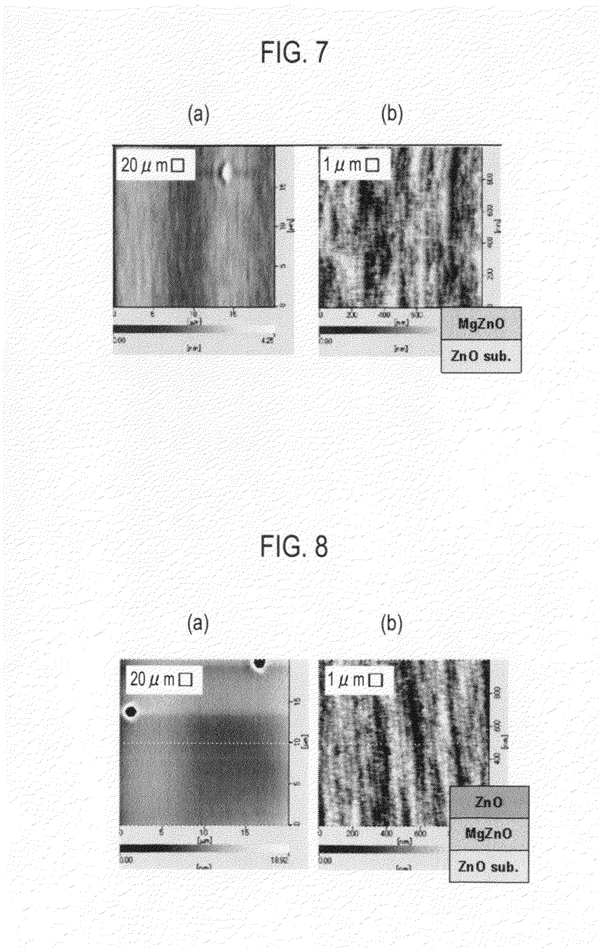

FIG. 7 shows images taken by AFM of the surface of MgZnO of ZnO substrate/undoped MgZnO formed at a growth temperature of 870° C. The density of crystal defects was 7.4×10⁴ cm⁻². In the meantime, FIG. 8 is of an undoped ZnO film formed on the undoped MgZnO film of FIG. 7 at a growth temperature of 870° C., and the surface of the undoped ZnO film was photographed as well by AFM. The density of crystal defects was 3.2×10⁵ cm⁻².

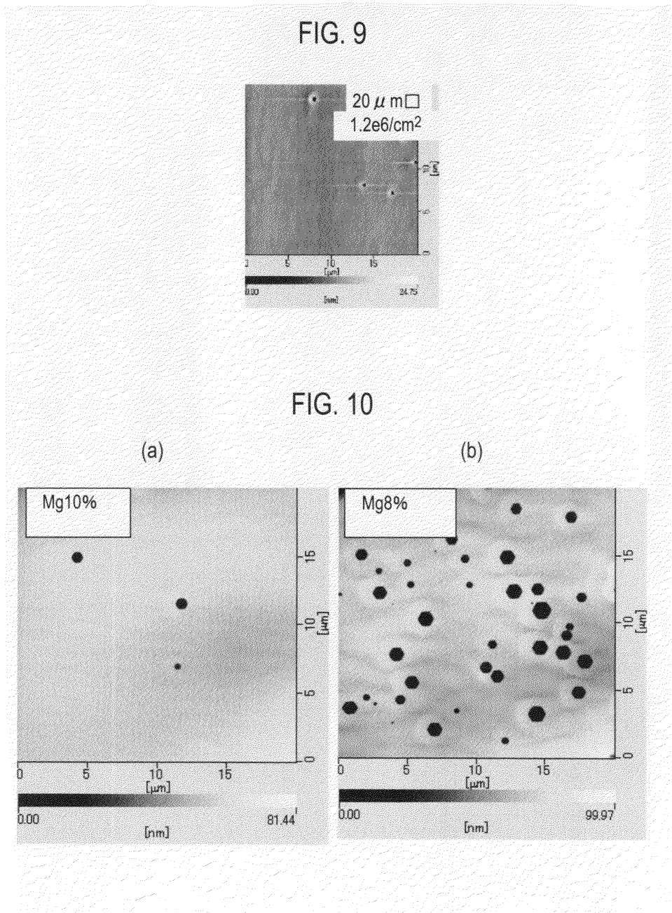

On the other hand, FIG. 9 shows an image obtained from the AFM measurement performed on the surface of an undoped ZnO film in ZnO substrate/undoped ZnO which is obtained by forming the undoped ZnO film directly on a ZnO substrate by crystal growth at a growth temperature of 870° C. without use of MgZnO as a base. In this case, the density of defects was 1.2×10⁶ cm⁻².

As shown in the measurements in FIG. 4 to FIG. 9, in the crystal growth at a relatively high temperature, defect in the MgZnO film formed on the ZnO substrate by crystal growth was smallest, whereas the density of defects when only ZnO is formed on the ZnO substrate by crystal growth indicates a double digit increase. In addition, it is shown that, when MgZnO is used as a base, an increase in the defect density of the ZnO film on MgZnO can be suppressed.

FIG. 10(a) is an image measured by AFM of the surface of nitrogen-doped Mg_{0.1}ZnO formed on a ZnO substrate at a growth temperature of 748° C. Meanwhile, FIG. 10(b) is an image measured by AFM of the surface of nitrogen-doped ZnO in the case where nitrogen-doped ZnO having a film thickness of 10 nm and nitrogen-doped Mg_{0.08}ZnO having a film thickness of 10 nm are laminated alternately for 20 cycles on a ZnO substrate at a growth temperature of 790° C. As can be seen here, when ZnO is repeatedly used in a laminate, the roughness of the surface of ZnO affects even the uppermost layer; therefore, the defect density increases. However, use of MgZnO as a base significantly suppresses such an increase in the defect density.

As described above, by use of an MgZnO layer, crystal defect in a MgZnO layer itself and in an upper layer formed after the MgZnO layer can be reduced, whereby the photoluminescence intensity of a thin film formed on the MgZnO layer is drastically increased. Therefore, the luminescence efficiency of a light emitting device can be improved.

Next, a method of manufacturing the ZnO-based semiconductor device having the structure of FIG. 1 will be described. A +C-plane ZnO substrate 1 is subjected to wet etching with an acid solution of pH 3 or below so as to remove a layer damaged by polishing. The ZnO substrate 1 is introduced through a load lock chamber into an MBE apparatus achieving a background vacuum of approximately 5×10⁻⁷ Pascal. While the temperature is monitored by thermography, the ZnO substrate 1 is heated at 700° C. to 1000° C. so as to sublime H₂O and hydrocarbon-based organic matters attached thereto in atmosphere (thermal cleaning).

At a growth temperature of 900° C., Ga-doped MgZnO layer/undoped MgZnO layer/MQW active layer are grown by use of a Ga-doped MgZnO layer as the n-type Mg_{z}ZnO layer 2. The MQW active layer 4 is formed by, for example, repeating a well layer ZnO of a film thickness of 1.5 nm and a barrier layer Mg_{0.15}ZnO of a film thickness of 6 nm for approximately 5 cycles. In this case, a ZnO layer may be included in the MQW active layer 4. When the last layer of the MQW active layer 4 is a ZnO layer, an undoped Mg_{0.15}ZnO layer, for example, is formed as the undoped Mg_{X}ZnO layer 5 on the MQW active layer 4 at a growth temperature of 900° C., as shown in FIG. 1. Next, the growth temperature is lowered to 850° C., and then plasma-cracked NO (nitrogen monoxide) gas is introduced so as to make a nitrogen-doped Mg_{0.15}ZnO grow as the acceptor-doped Mg_{Y}ZnO layer 6.

As described above, when an undoped MgZnO layer is used as a base of an acceptor-doped layer, the surface flatness can be improved even at a lower growth temperature in the formation of the acceptor-doped layer, whereby a sufficient amount of the acceptor element can be incorporated. Application of this can be applied as well to other devices than the above-described light-emitting device, for example, MOS-type and MIS-type FETs (field effect transistors), HEMTs (high electron mobility transistors), and the like.

For example, when a trench-type MOSFET is fabricated, an NPN structure having a p-type layer as a channel layer is available as well. In production of the NPN structure, the substrate temperature is raised when the growth process shifts from the p-type layer to the n-type layer. At this time, if a p-type ZnO is the last layer of the p-type layer, the p-type ZnO is likely to have defect at a high temperature. Accordingly, roughness occurs on the surface of the p-type ZnO, and further the surface roughness propagates to an n-type layer formed thereon, resulting in deterioration in the flatness of the surface thereof. In this case as well, by having formed an undoped MgZnO or a donor-doped MgZnO as the upper layer of the p-type layer, a subsequent n-type layer can be formed without causing surface roughness thereof.

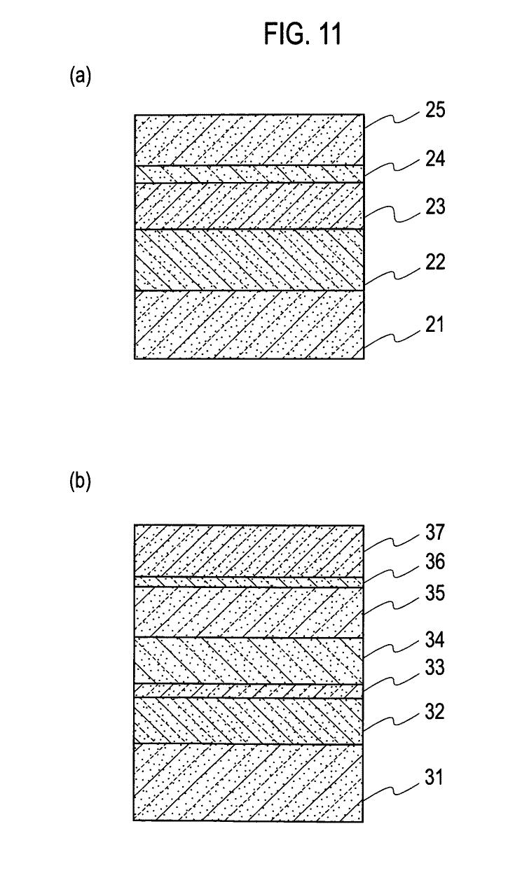

An NPN structure is adapted in MOS-type transistors, and its layer structure only is shown in FIG. 11(a). An n-type MgZnO layer 22, an acceptor-doped MgZnO layer 23, an undoped MgZnO layer 24, and an n-type MgZnO layer 25 are formed on a ZnO substrate 21. The acceptor-doped MgZnO layer 23 is converted into a p-type layer to form the NPN structure. The acceptor-doped MgZnO layer 23 corresponding to an acceptor-doped layer is formed with the n-type MgZnO layer 22 as a base, the n-type MgZnO layer 22 corresponding to a donor-doped Mg_{X}Zn_{1-X}O layer. Accordingly, the amount of acceptor element doping can be secured while the surface flatness of the acceptor-doped MgZnO layer 23 is improved. Even if the surface flatness of the acceptor-doped MgZnO layer 23 is deteriorated, the surface roughness would not propagate to the n-type MgZnO layer 25 because the n-type MgZnO layer 25 is fabricated with the undoped MgZnO layer 24 as a base:

FIG. 11(b) is an example of a laminate structure when two layers of acceptor-doped layer are formed. An acceptor-doped MgZnO layer 32, an undoped MgZnO layer 33, an n-type ZnO layer 34, an acceptor-doped MgZnO layer 35, an undoped MgZnO layer 36, and an n-type MgZnO layer 37 are formed on a ZnO substrate 31. Undoped MgZnO layers 33 and 36 (corresponding to the undoped Mg_{X}Zn_{1-X}O layer) are formed as the upper layer of the acceptor-doped MgZnO layers 32 and 35, respectively, so that the surface roughness of the acceptor-doped layers cannot propagate to their respective upper layers.

By using an undoped MgZnO layer or a donor-doped MgZnO layer in a layer before fabricating the acceptor-doped layers or a layer after the acceptor-doped layers and using MgZnO as well for the acceptor-doped layers, in such a way as described above, deterioration in the flatness and an increase in the defect density of the acceptor-doped layers and the layers above can be prevented.

As described above, it was found that, in fabrication of a ZnO-based semiconductor device, a thin film made of MgZnO is less likely to be dependent on parameters in the production process compared to a thin film made of ZnO alone. Next, it will be shown that use of MgZnO stabilizes properties and nature of a film, and that MgZnO is ideal for application not only to an acceptor-doped layer but also active operating layers, such as a light emitting layer and a channel layer, which exert a target function of a device. Note that, specific details of the active operating layer will be described later.

Most of the studies thus far made to convert a ZnO-based semiconductor (ZnO-based compound semiconductor) into a p-type one are about the p-type ZnO. Typical examples of ZnO-based semiconductors are CdZnO and MgZnO. CdZnO, which is a narrow-gap material, has been rarely studied because of the poisonous nature of Cd. MgZnO, which is a wide-gap semiconductor, has not been considered as a target for the study of conversion into p-type for the following reasons, for example. First, as a usually observed tendency of a wide-gap material, MgZnO has a larger energy for activating the accepter energy (i.e., it is more difficult to generate holes). In addition, it is difficult to increase the purity of MgZnO as it is often made from sintered bodies.

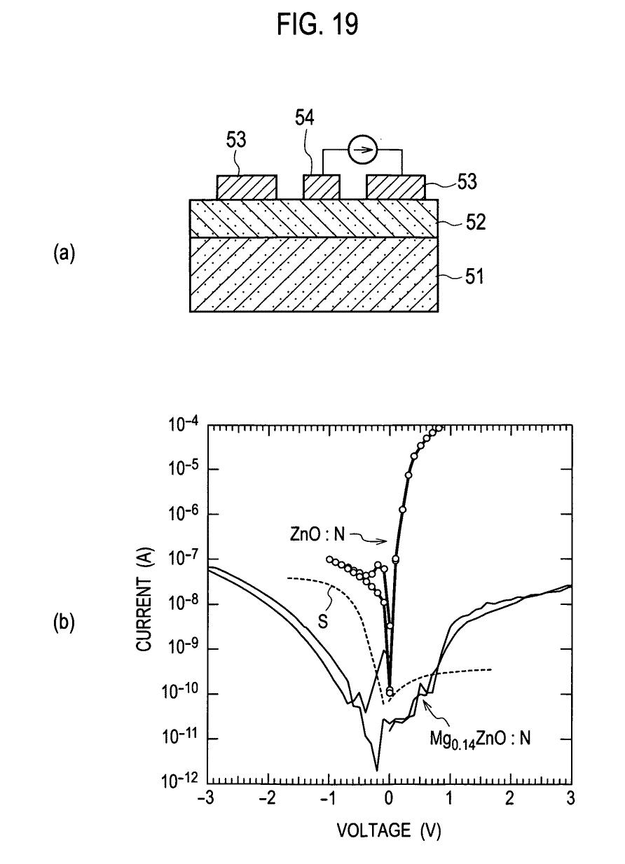

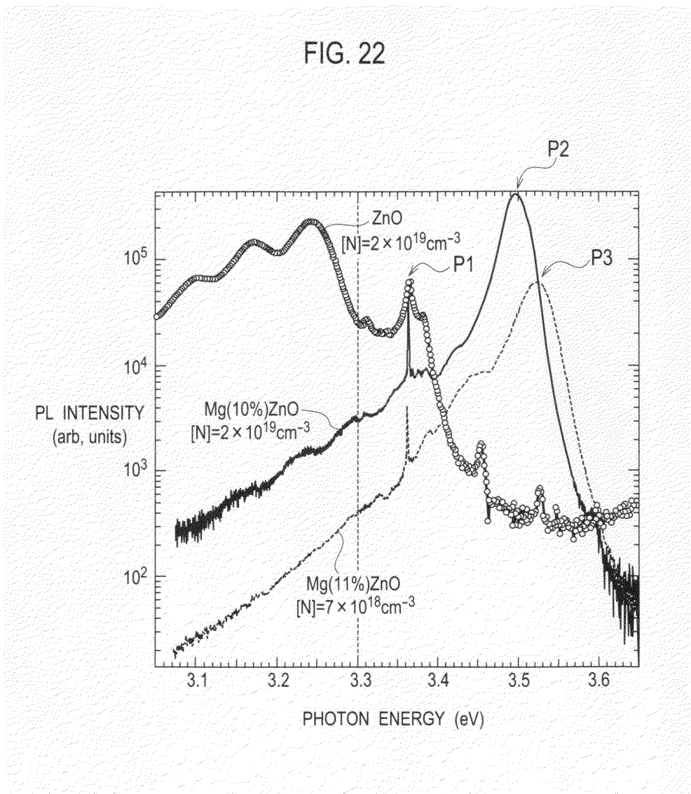

However, the inventors have discovered that Mg_{Y}Zn_{1-Y}O (0<Y<1), which is a kind of ZnO-based semiconductor, has an effect to reduce the self-compensation effect, which is a fact that had been unknown until then, and this is described in detail in Japanese Patent Application No. 2007-251482. The main points of the details will be described herein again. FIG. 22 shows that MgZnO has a special effect to reduce or alleviate the self-compensation effect. FIG. 22 illustrates spectrum distributions obtained by photoluminescence (PL) measurement performed on nitrogen-doped ZnO and two different kinds of nitrogen-doped MgZnO at an absolute temperature of 12 K (Kelvin). The PL measurement was performed on a structure obtained by crystallizing a nitrogen-doped Mg_{X1}ZnO layer 52 (0≦X1<1) on a ZnO substrate 51, as shown in FIG. 19(a), and the nitrogen-doped MgZnO was one formed through crystal growth of a nitrogen-doped MgZnO layer 52 (X1≠0) on the ZnO substrate 51. The nitrogen-doped ZnO was one formed through crystal growth of a nitrogen-doped ZnO layer 52 (X1=0) instead of the nitrogen-doped MgZnO layer.

Further, as a photoluminescence measurement apparatus, an apparatus described in Japanese Patent Application No. 2007-251482 which has been filed was used. In brief description, a He—Cd laser was used as an excitation light source, and the output of the He—Cd laser was within a range from 30 to 32 mW. The intensity of the excited light produced by the excitation light source was approximately within a range from 1 to 10 W/cm². The output of the excited light immediately before a sample was approximately within a range from 250 to 400 μW. The focal length of a spectroscope was 50 cm. Diffraction gratings were formed in the spectroscope at a pitch of 1200 gratings per millimeter. The blaze wavelength (the wavelength of maximum diffraction efficiency) was 330 nm. There was used a freezing apparatus capable of setting the freezing temperature within an absolute-temperature range from 10 to 200 K. A photodetector included CCD detectors and had a 1024-ch configuration. The photodetector was cooled by liquid nitrogen. The overall system including the spectroscope and the photodetector was what was known as SPECTRUM1 System (Manufactured by HORIBA JOVIN YVON).

In the measurement result shown in FIG. 22, a white-circle (∘) curve represents the nitrogen-doped ZnO whereas the other two curves represent the two different kinds of nitrogen-doped MgZnO. The measurement was performed under the condition that the concentration of the doped nitrogen for ZnO was set at 2×10¹⁹ cm⁻³, and, as to MgZnO, the concentration of doped nitrogen for Mg_{0.1}ZnO was set at 2×10¹⁹ cm⁻³ and the concentration of doped nitrogen for Mg_{0.11}ZnO was set at 7×10¹⁸ cm⁻³. The horizontal axis in FIG. 22 represents the photon energy (unit: eV) and the vertical axis represents the PL intensity. The unit for the vertical axis is an arbitrary unit that is usually used for PL measurement (i.e., logarithmic scale). For easy comparison among the shapes of the respective spectra, positions of the original points of the respective spectra are shifted from each other.

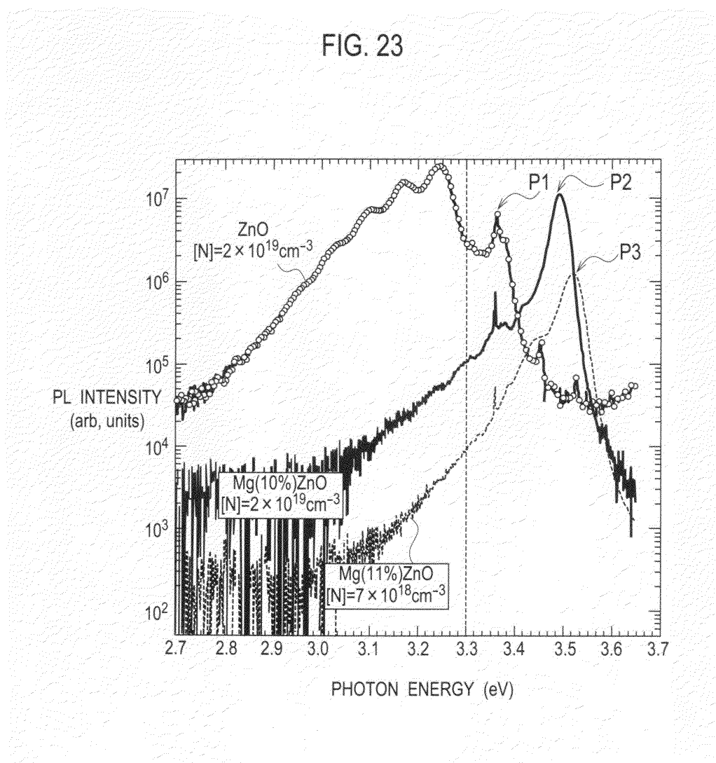

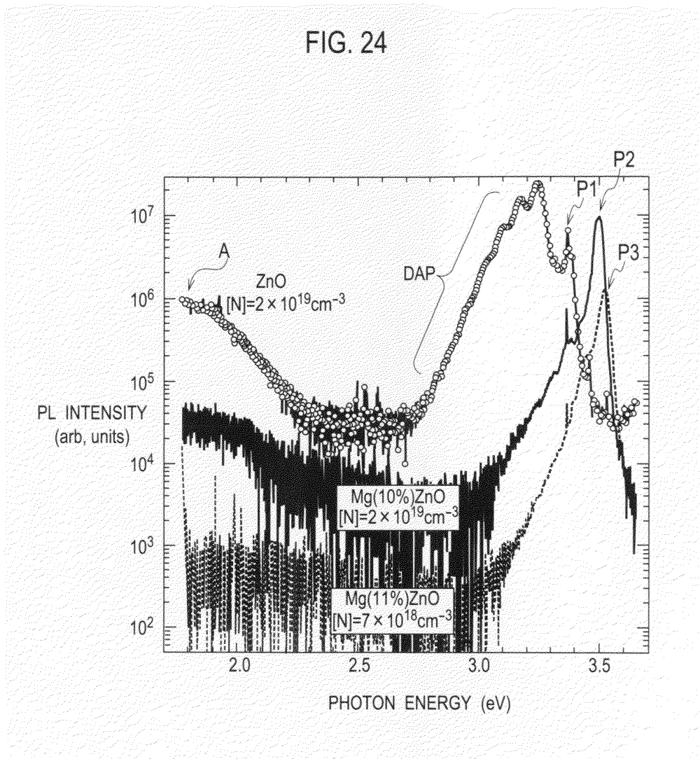

FIG. 24 shows a graph obtained by expanding the range of the horizontal scale of the graph in FIG. 22, which is from 3.05 to 3.65 eV, to a range from 1.7 to 3.7 eV. FIG. 23 is a graph obtained by expanding the horizontal scale of the graph in FIG. 22 to a range from 2.7 to 3.7 eV. The points P1, P2, P3 in each of FIGS. 22 to 24 represent the points where band edge luminescence occurred.

The point P1 in each of FIGS. 22 to 24 indicates the band edge luminescence peak energy of the nitrogen-doped ZnO. As has already been known, in the spectrum of the nitrogen-doped ZnO, a luminescence peak that is peculiar to the time of acceptor doping, known as donor-acceptor pair (DAP), appears at the lower energy side of the position P1. The position of the DAP luminescence is determined as follows.

When E_{DAP} is the energy of DAP luminescence, E_{G} is the minimum excitation energy, E_{D} is the donor level, E_{A} is the acceptor level, r_{DA} is the distance between the donor and the acceptor, ε₀ is the vacuum permittivity, εᵣ is the relative permittivity, e is the charges of electrons, h is the Planck's constant, and ω_{LO} is the LO (longitudinal-optical) phonon frequency, then

E_{DAP}=E_{G}−E_{D}−E_{A}+(e²/4πε₀εᵣr_{DA})−(mhω_{LO}/2π).

Here, m is an integer that is equal to or larger than zero.

The DAP luminescence peak position is determined by the equation above. So, given kinds of the donor and of the acceptor and their respective concentrations, the DAP luminescence peak position is determined.

If a line at 3.3 eV is the border to separate the region of band edge luminescence from the region of DAP luminescence, the region of DAP luminescence appears at the lower-energy side of the 3.3-eV line. In addition, as FIG. 24 shows, at a further lower-energy side of the DAP region, there is a region where as the energy becomes lower and lower, the PL intensity becomes higher and higher. A deep-level luminescence that is unique to the nitrogen doping can be observed. In an energy region that is close to A in FIG. 24, the intensity of the deep-level luminescence becomes significantly larger for the ZnO. The origin of this deep-level luminescence has not been identified; however, it is known to be due to a defect. A strong deep-level luminescence indicates occurrence of a large number of defects. The intensity of the deep-level luminescence for the MgZnO is more than one digit smaller than the corresponding intensity of the ZnO. This is a distinctive feature of MgZnO. In MgZnO, the degree of occurrence of defects due to nitrogen doping is small.

It is a well-known fact that as the density of the PL excitation light is raised, a blue shift of the luminescence peak of the DAP luminescence occurs. This phenomenon is means that is principally used for identifying the DAP luminescence. The solid-line curve and the dashed-line curve are of the wide-gap MgZnO. So, along the curves of the MgZnO, similar peaks to the band edge luminescence peak for the ZnO are observable, though slightly, at the same positions as that of the band edge luminescence peak P1 for the ZnO. This observation leads to easy understanding of the fact that in the case of the nitrogen-doped ZnO, the DAP luminescence is stronger than the ZnO band edge luminescence when the photon energy equals 3.3 eV or smaller. In the case of ZnO, the band edge luminescence becomes weaker and the DAP luminescence becomes stronger at the time of acceptor doping. Such a trend can be observed also in the cases of ZnSe and GaN, and is therefore quite normal. The fact is a reason why ZnO has been the commonly used material for the conversion into p-type.

The behavior of MgZnO is totally different as FIGS. 22 to 24 show. In each of FIGS. 22 to 24, the dashed line and the solid line represent the nitrogen-doped MgZnO of two different kinds. Both of the lines indicates that the luminescence in the vicinities of the band edge luminescence P2 and P3 is stronger than the DAP luminescence. In particular, the data shown by the solid line have quite weak DAP luminescence though the nitrogen concentration of this MgZnO is equal to the concentration of the ZnO curve. Such weak DAP luminescence is a noticeable characteristic of MgZnO, and can be considered as a phenomenon associated with the reduction in the self-compensation effect.

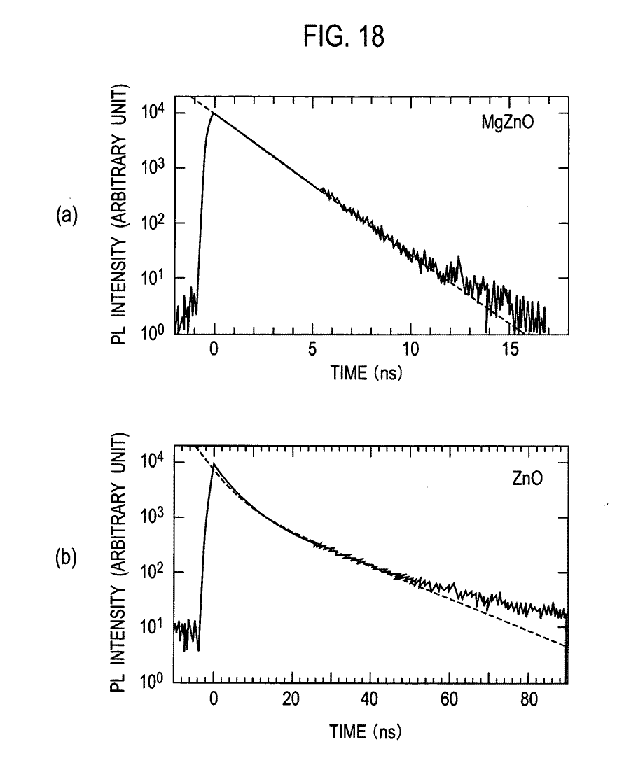

On the other hand, as described above, a nitrogen-doped MgZnO has an extremely smaller intensity of the deep-level luminescence than that of a nitrogen-doped ZnO. This indicates that the occurrence of point defects in nitrogen doping is small in MgZnO, and the same tendency can be observed as well between undoped MgZnO and undoped ZnO. FIG. 18 shows that MgZnO has less extra levels outside of the vicinity of the band than ZnO. FIG. 18 is called time-resolved photoluminescence (TRPL), which shows how the PL light intensity is attenuated with the time elapsed after excitation by an external laser in the horizontal axis and the PL light intensity (in this case, the intensities of the band edge of ZnO and MgZnO) at a certain selected wavelength in the vertical axis, and which is used for estimating a light emitting component and a non-light emitting component.

FIG. 18(a) shows a TRPL spectrum of MgZnO whereas FIG. 18(b) shows a TRPL spectrum of ZnO. Here, in both FIGS. 18(a) and (b), the horizontal axis represents the time elapsed (unit: ns) after the first PL light emission whereas the horizontal axis represents the PL intensity which is expressed in an arbitrary unit (logarithmic scale) commonly used in PL measurement.

The exponential attenuation of the PL intensity in the chronological change of the PL intensity indicates that there is no extra luminescence level. When the logarithm of PL intensity is plotted on a graph, a resultant curve is desirably a linear line. The solid line represents the result of fitting of a measured curve fitted with a combination of multiple exponential functions. If the curve is a linear line, only one exponential function is used. While ZnO does not provide a linear line as shown in FIG. 18(b), MgZnO provides a linear line as shown in FIG. 18(a). Accordingly, it is found that MgZnO has fewer occurrences of extra levels, is easier to be optimized, has a wider permissive range of the growth conditions, and thereby is suitable as a device material. In addition, it is considered that MgZnO in comparison with ZnO is more likely to be converted into p-type by the acceptor doping due to the reduction in the self-compensation effect, and this will be described below.

In the configuration shown in FIG. 19(a), an electrode 53 made of Hg (mercury) and an electrode 54 are provided on a nitrogen-doped Mg_{X1}ZnO layer 52. The electrode 53 is formed in a circular shape with the electrode 54 at the center in such a manner as to surround the electrode 54. The electrodes 53 and 54 are in Schottky contact with the nitrogen-doped ZnO layer; however, this contact can be considered to be ohmic contact because the area of the electrode 53 is larger by one digit or more. FIG. 19(b) is a graph which is plotted in such a way that the voltage when the electrode 54 is biased to positive relative to the electrode 53 is positive. FIG. 19(b) shows the current-voltage characteristics (IV characteristics) of the configuration shown in FIG. 19(a) with the voltage (unit: V) in the horizontal axis and the electric current (unit: A) in the vertical axis.

If the nitrogen-doped Mg_{X1}ZnO layer 52 is n-type, application of a positive voltage to the electrode 54 results in lowering the potential barrier to the electrons in the electrode side; therefore, the electrons flow from the side of the nitrogen-doped Mg_{X1}ZnO layer 52. On the other hand, if the nitrogen-doped Mg_{X1}ZnO layer 52 is p-type, application of a positive voltage to the electrode 54 results in raising the potential barrier to the positive holes; therefore, no electric current flows. Conversely, application of a negative voltage to the electrode 54 results in lowering the potential barrier to the positive holes; therefore an electric current flows.

Accordingly, an ideal curve at the conversion of the nitrogen-doped Mg_{X1}ZnO layer 52 into p-type should be a curve S shown by the dotted line. The IV characteristics were compared between the cases, both with an amount of nitrogen doping of the nitrogen-doped Mg_{X1}ZnO layer 52 set to be approximately 1×10¹⁹, of the nitrogen-doped ZnO layer 52 obtained by changing the Mg composition to X=0 and of the nitrogen-doped Mg_{0.14}ZnO layer 52 obtained by changing the Mg composition X=0.14. The “:N” in the diagram indicates nitrogen doping. As can be seen from FIG. 19(b), ZnO remains to be n-type with an amount of nitrogen doping of approximately 1 ×10¹⁹, whereas MgZnO takes the characteristic close to the curve S, that is, the p-type behavior. Accordingly, the activation of nitrogen doping is more likely to occur with MgZnO. Thus, MgZnO is suitable for constituting an acceptor-doped layer.

Further, as described above, in view of easiness of optimization, suitability as a device material because of its wide permissive range of the growth conditions, exerting the base effect, having less roughness of the film surface, having an effect of reducing crystal defect, and the like, formation of an active operating layer, which functionally works in a device, with MgZnO containing a component of Mg instead of using a ZnO crystal alone is more advantageous in terms of process stability.

Herein, an active operating layer is a layer which works actively not passively, and refers to, for example, ones having the following configurations. First, an active operating layer is a light emitting layer or a portion of a light emitting region in an LED (light emitting diode) and an LD (laser diode). A p-type layer and an n-type layer when the light emitting region is formed by pn junction correspond to this light emitting layer or portion of the light emitting region. Further, a laminate and the like, such as an MQW (Multi Quantum Well) active layer and an SQW (Single Quantum Well) active layer, which have a multi quantum well structure, are also included. Second, an active operating layer is a channel layer, in which population inversion occurs, in a field effect transistor (FET) having an MOS (Metal Oxide Semiconductor) structure, an MIS (Metal

Insulator Semiconductor) structure, or the like. Third, an active operating layer is, in a photodiode (PD), a light absorbing layer or a layer in which a rectifying action occurs. For example, a Schottky junction is formed when metal and a semiconductor layer come in contact with each other, and this semiconductor layer corresponds to an active operating layer. A structure is formed in which MgZnO containing a component of Mg instead of ZnO crystal alone is used for the active operating layer described above. In TFT, the channel portion is made of MgZnO.

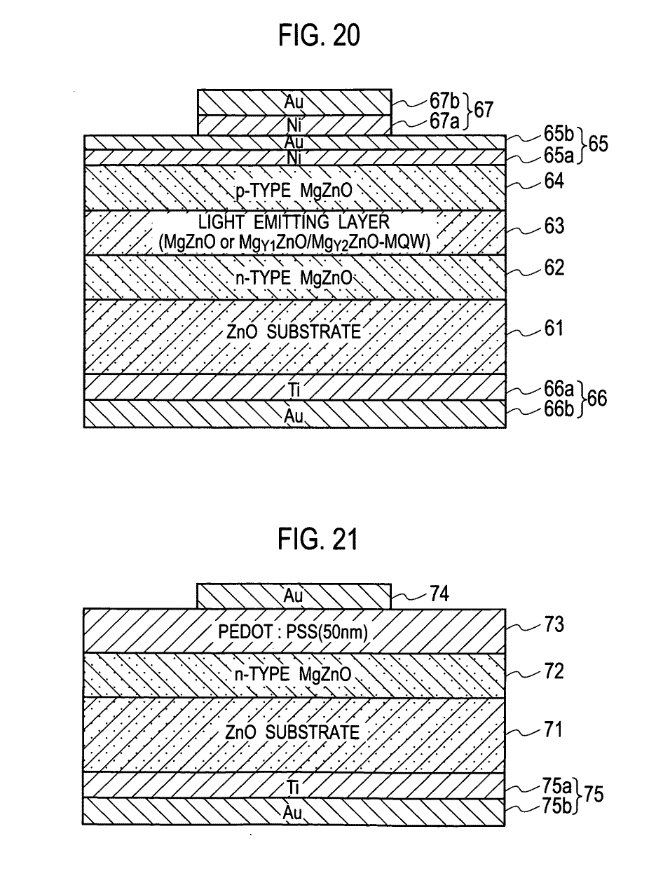

FIG. 20 shows an example of the structure of an LED (light emitting diode) using MgZnO for its active operating layer. An n-type MgZnO layer 62, an active layer 63, and a p-type MgZnO layer 64 are formed on a ZnO substrate 61. The p-type MgZnO layer 64 corresponds to an acceptor-doped layer. The active layer 63 is formed with a MgZnO layer alone or with a multi quantum well (MQW) structure in which a Mg_{Y1}ZnO layer (0<Y1<1) is sandwiched between Mg_{Y2}ZnO layers (0<Y2<1, Y1<Y2) having a larger band gap than that of the Mg_{Y1}ZnO layer. Further, a p electrode 65 which is formed with a Ni film 65a and a Au film 65b is disposed on the p-type MgZnO layer 64, whereas an n electrode 66 which is formed with a Ti film 66a and a Au film 66b is disposed on the rear surface of the ZnO substrate 61. A wire bonding electrode 67 which is formed with a Ni film 67a and a Au film 67b is formed on the p electrode 65. In this case, the active layer 63 which serves as a light emitting layer corresponds to an active operating layer.

FIG. 21 shows an example of the structure of a photodiode using MgZnO for its active operating layer. An n-type MgZnO layer 72 and an organic electrode PEDOT: PSS73 are formed on a ZnO substrate 71. The PEDOT: PSS73 is formed to have a film thickness of, for example, approximately 50 nm, and a Au film 74 for wire bonding is formed on the PEDOT: PSS73. In the meantime, an electrode 75 which is formed with a Ti film 75a and a Au film 75b is formed on the rear surface of the ZnO substrate 71. In this case, the PEDOT: PSS73 and the n-type MgZnO layer 72 are in a state of a Schottky junction. Accordingly, the n-type MgZnO layer 72 takes the role of a light absorbing layer or a layer in which a rectifying action occurs, thereby corresponding to an active operating layer.

In addition, in the case of the MOS-type transistor having an NPN structure as described above in FIG. 11(a), the p-type layer is a channel layer. Accordingly, the acceptor-doped MgZnO layer 23 corresponds to a channel layer. This case, however, is an example in which the acceptor-doped MgZnO layer 23 has the functions of both of an acceptor-doped layer and an active operating layer. In FIG. 11(b), the acceptor-doped MgZnO layer 35 corresponds to both of an acceptor-doped layer and an active operating layer. It should be noted that the configuration of the semiconductor device of the present invention is not limited to the examples described above, and various examples and the like which are not described herein are also included.

1. A ZnO-based semiconductor device formed by laminating a ZnO-based semiconductor on a substrate by crystal growth, the ZnO-based semiconductor device comprising an acceptor-doped layer which is composed of Mg_{Y}Zn_{1-Y}O (0<Y<1) and contains at least one kind of an acceptor element, wherein an undoped or donor-doped Mg_{X}Zn_{1-X}O (0<X<1) layer is formed in contact with the acceptor-doped layer.

2. A ZnO-based semiconductor device formed by laminating a ZnO-based semiconductor on a substrate by crystal growth, the ZnO-based semiconductor device comprising:
an acceptor-doped layer which is composed of Mg_{Y}Zn_{1-Y}O (0<Y<1) and contains at least one kind of an acceptor element; and
an n-type Mg_{Z}Zn_{1-Z}O (0≦Z<1) layer which contains at least one kind of a donor element, wherein
an undoped or donor-doped Mg_{X}Zn_{1-X}O layer is formed to be located between the acceptor-doped layer and the n-type Mg_{Z}Zn_{1-Z}O layer and be in contact with any one of these two layers.

3. The ZnO-based semiconductor device according to claim 1, wherein the acceptor-doped layer is formed closer to the substrate.

4. The ZnO-based semiconductor device according to claim 1, wherein a Mg composition X of the undoped or donor-doped Mg_{X}Zn_{1-X}O layer is in a range of 0<X ≦0.5.

5. The ZnO-based semiconductor device according to claim 1, wherein the at least one acceptor element of the acceptor-doped layer is nitrogen.

6. The ZnO-based semiconductor device according to claim 1, wherein the at least one donor element of the n-type Mg_{Z}Zn_{1-Z}O layer is a III-group element.

7. The ZnO-based semiconductor device according to claim 1, wherein
an active operating layer which exerts a target function of the device is formed in addition to the acceptor-doped layer, and
the active operating layer is composed of MgZnO.

8. The ZnO-based semiconductor device according to claim 2, wherein the acceptor-doped layer is formed closer to the substrate.

9. The ZnO-based semiconductor device according to claim 2, wherein a Mg composition X of the undoped or donor-doped Mg_{X}Zn_{1-X}O layer is in a range of 0<X≦0.5.

10. The ZnO-based semiconductor device according to claim 2, wherein the at least one acceptor element of the acceptor-doped layer is nitrogen.

11. The ZnO-based semiconductor device according to claim 2, wherein the at least one donor element of the n-type Mg_{Z}Zn_{1-Z}O layer is a III-group element.

12. The ZnO-based semiconductor device according to claim 2, wherein an active operating layer which exerts a target function of the device is formed in addition to the acceptor-doped layer, and the active operating layer is composed of MgZnO.
